(19) United States
(12) Patent Application Publication
(10) Pub. No.: US 2023/0188121 A1
(43) Pub. Date: Jun. 15, 2023

(54) APPARATUS AND METHOD FOR ENTROPY GENERATION

(71) Applicants: KOREA ATOMIC ENERGY RESEARCH INSTITUTE, Daejeon (KR); ELECTRONICS AND TELECOMMUNICATIONS RESEARCH INSTITUTE, Daejeon (KR)

(72) Inventors: Jong Bum KIM, Daejeon (KR); Jin Joo KIM, Sejong-si (KR); Kyung Hwan PARK, Daejeon (KR); Seong Mo PARK, Daejeon (KR); Kwang Jae SON, Sejong-si (KR); Byoung Gun CHOI, Daejeon (KR); Sang Mu CHOI, Daejeon (KR); Jin Tae HONG, Daejeon (KR); Jin KIM, Sejong-si (KR); Tae Wook KANG, Daejeon (KR); Ki Su KIM, Sejong-si (KR)

(21) Appl. No.: 18/080,816

(22) Filed: Dec. 14, 2022

(30) Foreign Application Priority Data
Dec. 14, 2021 (KR) 10-2021-0179097

(51) Int. Cl. H03K 3/0232; H03K 3/84

(52) U.S. Cl. CPC H03K 3/0232; H03K 3/84

(57) ABSTRACT

Disclosed is an entropy generation apparatus, which includes a detector that detects particles emitted from the radiation source to generate a detection signal; a preamplifier that amplifies the detection signal to generate an amplified signal; a filter that filters the amplified signal to generate a filtered signal; and a comparator that generates a pulse based on a result of comparing the filtered signal with a threshold value.

### CROSS-REFERENCE TO RELATED APPLICATIONS

This application claims priority under 35 U.S.C. §119 to Korean Patent Application No. 10-2021-0179097, filed on Dec. 14, 2021 in the Korean Intellectual Property Office, the disclosures of which are incorporated by reference herein in its entireties.

### BACKGROUND

### (A) Technical Field

The embodiments described herein relate to an apparatus and method for entropy generation.

### (B) Background Art

Random numbers are widely used for message encryption in secure communication, statistical sampling, and engineering calculations. In particular, random numbers used for secure communication, such as an Internet of Things (IoT), should be difficult or impossible to predict to prevent hacking.

Random number generation technology may be divided into pseudo random number-based technology and hardware-based random number technology. The pseudo random number-based technology is a technique of implementing a random number generation algorithm with a program, and the hardware-based random number technology is a technique of generating a random number using an irregular physical signal. The pseudo random numbers look like random numbers, but are inherently predictable because they are implemented by algorithms. In comparison, the hardware-based random numbers are closer to real random numbers because they are unpredictable.

The hardware-based random numbers may be divided into natural random numbers and quantum random numbers. The natural random numbers are random numbers based on a naturally occurring signal, and the random numbers are generated using thermal noise, semiconductor noise, or the like. The quantum random numbers may include radioactive decay random numbers, optical random numbers, or the like. Since random numbers may be generated more randomly using a quantum behavior that is not affected by the environment, the quantum random numbers may be generated most closely to a real random number among the hardware-based random numbers.

### [PRIOR ART DOCUMENTS]

### [Patent Documents]

(Patent Document 1) Korean Patent Publication No. 10-2289084
(Patent Document 2) Korean Patent Publication No. 10-1958757

### SUMMARY OF THE INVENTION

Methods obtaining entropy sources using the quantum behavior include a photon detection method using a light source and a signal detection method using a radioactive isotope decay. The signal detection method using the radioactive isotope decay in the above methods has an advantage in security when applied to the loT field because the chip size can be miniaturized. Therefore, among the radioactive decay methods, a random number generation method using an alpha source, which is easy to detect a signal, has been developed. In contrast, the alpha source has a low random number generation rate due to the low quantity exempted from regulation, and is difficult to use for a long time because it destroys a semiconductor sensor. On the other hand, when low-energy beta ray is used, it is possible to make a random number generator with a high random number generation rate due to the high quantity exempted from regulation, and the low-energy beta ray has advantages of a long-term use because it does not affect the semiconductor sensor.

Since the low-energy beta ray generates a smaller signal than the alpha ray, in order to detect the small beta ray signal, the influence of inherent noise generated inside the electronic circuit should be reduced. In this case, the reduction of intrinsic noise using external cooling is not suitable for miniaturization of the chip size, so reducing the influence of intrinsic noise should be performed through noise reduction design of the circuit.

According to an embodiment of the present disclosure, an entropy generation apparatus includes a detector that detects particles emitted from the radiation source to generate a detection signal; a preamplifier that amplifies the detection signal to generate an amplified signal; a filter that filters the amplified signal to generate a filtered signal; and a comparator that generates a pulse based on a result of comparing the filtered signal with a threshold.

According to an embodiment of the present disclosure, an entropy generation method includes generating a detection signal by detecting particles emitted from the radiation source; generating an amplified signal by amplifying the detection signal; generating a filtered signal by filtering the amplified signal; and generating a pulse based on a result of comparing the filtered signal with a threshold.

### BRIEF DESCRIPTION OF THE DRAWINGS

The above and other objects and features of the present disclosure will become apparent by describing in detail embodiments thereof with reference to the accompanying drawings.

FIG. 1 is a diagram illustrating an entropy generation apparatus, according to an embodiment of the present disclosure.

FIG. 2 is a diagram illustrating a structure of a PIN diode, according to an embodiment of the present disclosure.

FIG. 3 is a circuit diagram illustrating a structure of a preamplifier, according to an embodiment of the present disclosure.

FIG. 4 is a diagram illustrating a DC connection method and an AC connection method of a preamplifier, according to an embodiment of the present disclosure.

FIG. 5 is a diagram illustrating a configuration of a filter, according to an embodiment of the present disclosure.

FIG. 6 is a diagram illustrating an entropy generation apparatus further including a monostable multivibrator, according to an embodiment of the present disclosure.

FIGS. 7 and 8 are diagrams for describing an operation of a monostable multivibrator of the entropy generation apparatus, according to an embodiment of the present disclosure.

FIG. 9 is a diagram illustrating an entire circuit of an entropy generation apparatus, according to an embodiment of the present disclosure.

FIG. 10 is a flowchart for describing an entropy generation method, according to an embodiment of the present disclosure.

### DETAILED DESCRIPTION

Hereinafter, various embodiments of the disclosure will be described with reference to accompanying drawings. However, those of ordinary skill in the art will recognize that modification, equivalent, and/or alternative on various embodiments described herein can be variously made without departing from the scope and spirit of the disclosure.

In this specification, the singular form of a noun corresponding to an item may include one item or a plurality of items, unless the relevant context clearly dictates otherwise. In this specification, each of the phrases such as “A or B”, “at least one of A and B”, “at least one of A or B”, “A, B, or C”, “at least one of A, B, and C”, and “at least one of A, B, or C” may include any one of the items listed together in the corresponding one of the phrases, or all possible combinations thereof. Terms such as “first”, “second”, or “first” or “second” may simply be used to distinguish a given component from other corresponding components, and do not limit the components in any other respect (e.g., importance or order). When a certain (e.g., first) component is mentioned to be “coupled” or “connected” to another (e.g., second) component, with or without the terms “functionally” or “communicatively”, that means that the certain component can be connected to the other component directly (e.g., by wire), wirelessly, or through a third component.

Each component (e.g., module or program) of the components described in this specification may include singular or plural entities. According to various embodiments, one or more components or operations among corresponding components may be omitted, or one or more other components or operations may be added. Alternatively or additionally, a plurality of components (e.g., modules or programs) may be integrated into a single component. In this case, the integrated component may perform one or more functions of each of the plurality of components identically or similarly to those performed by a corresponding component among the plurality of components prior to the integration. According to various embodiments, operations performed by modules, programs, or other components are executed sequentially, in parallel, iteratively, or heuristically, one or more of the operations are executed in a different order, omitted, or one or more other operations may be added.

As used in this specification, the term “module” or “... unit” may include units implemented in hardware, software, or firmware, and may be interchangeably used with terms such as, for example, logic, logic blocks, parts, or circuits. The module may be an integral part or the smallest unit of a part or part thereof that performs one or more functions. For example, according to one embodiment, the module may be implemented in the form of an application-specific integrated circuit (ASIC).

Various embodiments of the present document may be implemented as software (e.g., a program or application) including one or more instructions stored in a storage medium (e.g., a memory) readable by a machine. For example, a processor of the machine may invoke at least one command among one or more instructions stored from a storage medium and execute it. This enables the machine to be operated to perform at least one function according to the at least one command invoked. The one or more instructions may include code generated by a compiler or code executable by an interpreter. The machine-readable storage medium may be provided in the form of a non-transitory storage medium. Here, ‘non-transitory’ only means that the storage medium is a tangible device and does not contain a signal (e.g., electromagnetic waves), and this term does not distinguish between a case where data are semi-permanently stored in a storage medium and a case where data are temporarily stored.

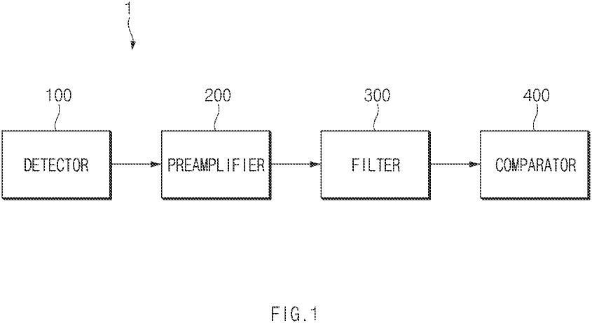

FIG. 1 is a diagram illustrating an entropy generation apparatus, according to an embodiment of the present disclosure.

Referring to FIG. 1, an entropy generation apparatus 1 may include a detector 100, a preamplifier 200, a filter 300, and a comparator 400.

The entropy generation apparatus 1 may generate random numbers based on a signal source (entropy source) that generates random signals. The entropy generation apparatus 1 may generate a pulse for generating a random number from a randomly generated signal. For example, the signal source may be a radiation source, and the radiation source may generate a random signal upon radioactive decay. A random number may be generated using a pulse generated by the entropy generation apparatus 1 through random number generating software, a processor, or a module. Hereinafter, the configuration and operation of the entropy generation apparatus 1 will be described in more detail.

The detector 100 may generate a detection signal by detecting particles emitted from a radiation source. For example, the detection signal may be a current signal. A radiation source may refer to a device or material that emits radiation from the decay of a radioactive element. According to an embodiment, the radiation source may include a beta ray source. For example, nickel isotope (Ni-63) and hydrogen isotope (H-3) that emit beta rays may be used as a radiation source.

When a beta ray source is used as the radiation source, since the beta ray source has a high number of regulatory exemptions, when using the beta ray source, high-speed random number generation using multiple channels is possible, and the random number generation rate may be increased. In addition, beta rays generated from the beta ray source have lower energy than alpha rays, and thus have little effect on circuit configurations including the detector 100 to prevent damage and may be used for a long period of time.

The detector 100 may detect particles through a change in current or voltage generated when particles emitted from a radiation source are collided. The particles emitted from the radiation source have energy, and when the particles collide with the detector 100, a current corresponding to the particle energy is generated in the detector 100. In this case, the integral value of the generated current is proportional to the radiation energy. The detector 100 may detect a current generated due to collision with the particles and may generate a detection signal therefrom. According to an embodiment, the detector 100 may include a PIN diode.

The preamplifier 200 may generate an amplified signal by amplifying the detection signal generated by the detector 100. For example, the amplified signal may be a voltage signal. As described above, the entropy generation apparatus 1 may use a beta ray source as the radiation source, and in this case, the magnitude of the detection signal generated by the detector 100 may also be small because the energy of the beta ray is small. The preamplifier 200 may then amplify the detection signal to generate a pulse through signal processing.

According to an embodiment, the preamplifier 200 may have a single ended structure. When the preamplifier 200 has the single ended structure, noise generation may be reduced compared to a structure in which power is input to both ends, such as a differential amplifier. According to the embodiment, in the single ended structure, a non-inverting terminal of the preamplifier 200 is grounded and an inverting terminal of the preamplifier 200 is connected to the detector 100 to be amplified as an inverted signal.

The filter 300 may filter the signal amplified by the preamplifier 200 to generate a filtered signal. The filter 300 may receive a signal and pass or block a signal corresponding to a specific frequency. According to an embodiment, the filter 300 may include a low pass filter (LPF), a high pass filter (HPF), a band pass filter (BPF), and the like according to frequency characteristics, but is not limited thereto.

The filter 300 may reduce noise by filtering the amplified signal. The filter 300 may reduce an amount of noise included in the signal by blocking and not passing a part of the signal according to a frequency. In addition, noise may be generated differently for each frequency domain depending on the circuit configuration, and the filter 300 may reduce noise and increase a signal-to-noise ratio (SNR) by blocking a frequency domain where a lot of noise occurs. The signal-to-noise ratio is a value obtained by dividing the signal intensity by the noise intensity (signal intensity/noise intensity) and is a measure of signal quality, as the signal-to-noise ratio increases, the signal quality is better. For example, when a lot of noise occurs in a low band (low-frequency), the filter 300 may increase the signal-to-noise ratio by not passing a low band signal using a high pass filter. (For example, when a lot of noise occurs in a low band, since the SNR in a low band is lower than the SNR in a high band, the SNR of the entire signal may be increased by blocking the low band signal.)

According to an embodiment, the filter 300 may include an amplifier that further amplifies the amplified signal. To this end, the filter 300 may include an active filter, and the active filter may perform signal amplification and filtering. The filter 300 may perform additional amplification when the amplified signal of the preamplifier 200 is too small to operate the comparator 400.

The comparator 400 may generate a pulse based on a result of comparing the filtered signal with a threshold. The threshold may mean a reference value for determining whether to generate a pulse. Since the comparator 400 generates a pulse when particles emitted from the radiation source are detected, the threshold may be set to a value greater than the intensity of general noise so that the pulse is not generated by the noise signal. The threshold may have a different value depending on the structure of the circuit or the intensity of noise. According to an embodiment, the comparator 400 may compare the filtered signal with the threshold and may generate the pulse when the magnitude of the filtered signal is greater than or equal to the threshold.

The duration of the analog signal of the filtered signal generated by the filter 300 is determined depending on the time constant of the filter 300. In this case, the duration of the output signal may be changed depending on the magnitude of the input signal of the comparator 400. In this case, the comparator 300 may set an operating time for generating the pulse longer than the duration of the analog signal. For example, the operating time of the comparator 300 may be set to twice the duration of the analog signal.

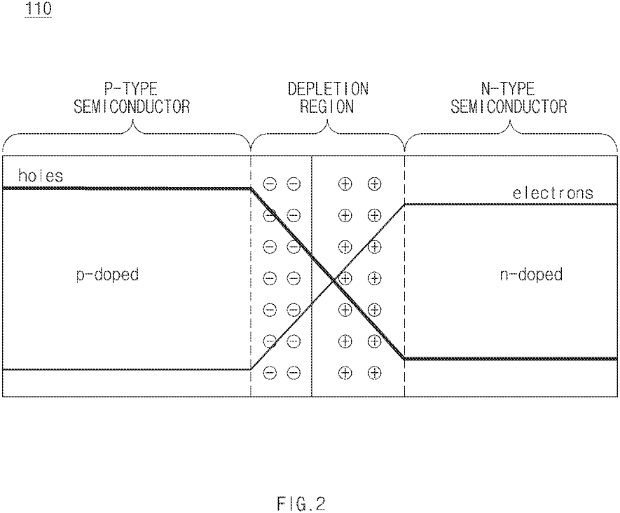

FIG. 2 is a diagram illustrating a structure of a PIN diode, according to an embodiment of the present disclosure.

Referring to FIG. 2, the detector 100 may include a PIN diode 110. According to an embodiment, the PIN diode 110 may have a PN junction structure in which a p-type semiconductor and an n-type semiconductor are coupled with a depletion region therebetween.

When the PIN diode 110 is used, the entropy generation apparatus 1 may be miniaturized compared to the case of using detection elements such as an avalanche photo diode (APD), a silicon photomultiplier (SiPM), or the like. Since the avalanche photo diode needs to apply a high voltage on average, it is difficult to miniaturize because it requires a separate high voltage device. In addition, since the silicon photomultiplier has a large area and requires a scintillator, it is difficult to miniaturize.

According to an embodiment, the PIN diode 110 may reduce noise by adjusting an area, a thickness of a depletion region, and the like. In the case of a general radiation meter, measurement efficiency may be increased as the light-receiving area and depletion area are wider, so the PIN diode used in the radiation meter tends to make the light-receiving area and depletion area of the diode larger. This is because radiation measurement efficiency increases as the light-receiving area and depletion region of the PIN diode increase. However, in this case, there is a problem in that the operating voltage for full depletion increases and the self-capacitance increases. For example, in the case of a general radiation meter, a voltage of about 70-100V is required for full depletion, and in this case, the self-capacitance becomes more than 40pF. In this case, since the radiation meter requires an additional configuration such as a separate high voltage generator, it is difficult to miniaturize the integrated circuit. Therefore, it is not suitable for security fields that require miniaturization of the chip size, such as the loT.

In addition, there is a problem that self-noise also increases in proportion to self-capacitance. Therefore, according to the embodiment, since the PIN diode 110 may operate even at a low voltage (e.g., 12V or less) by reducing the thickness and depletion region of the PIN diode 110, the self-noise of the detector 100 is reduced according to the reduced light-receiving area.

In addition, when using a beta ray source, since the beta ray has low penetrating power, there may be a problem of not being able to transmit when the thickness of the PIN diode 110 is large. However, by reducing the thickness of the PIN diode 110, the detector 100 may effectively detect beta rays and generate a detection signal even when the beta ray source is used as the radiation source.

According to an embodiment, the PIN diode 110 of the detector 100 may be configured to have a detection capacitance of 10 picofarads (pf) or less. Here, the detection capacitance may mean the inherent capacitance of the PIN diode 110. The detection capacitance may vary depending on the size of the PIN diode 110, the thickness of the depletion region, and the like, and the detection capacitance may increase as the size of the PIN diode 110 increases. As the detection capacitance of the PIN diode 110 decreases, the noise caused by the PIN diode 110 decreases. Therefore, the detector 100 may be designed with a small detection capacitance to reduce inherent noise caused by the PIN diode 110. For example, the detector 100 may reduce noise by setting the area of the PIN diode 110 to 10 mm² or less to reduce the detection capacitance. In addition, by setting the thickness of the depletion region to 100 µm (micrometer) or less, full depletion may be achieved even at a low voltage.

That is, the detector 100 may reduce noise by reducing detection capacitance by reducing the area and depletion region, and may have performance optimized for entropy generation because it can be used at a low voltage.

According to the embodiment, each PIN diode 110 constituting the detector 100 may have a detection capacitance of 100 femtofarads (fp) or more. However, it is not limited thereto, and may have a smaller detection capacitance in some cases.

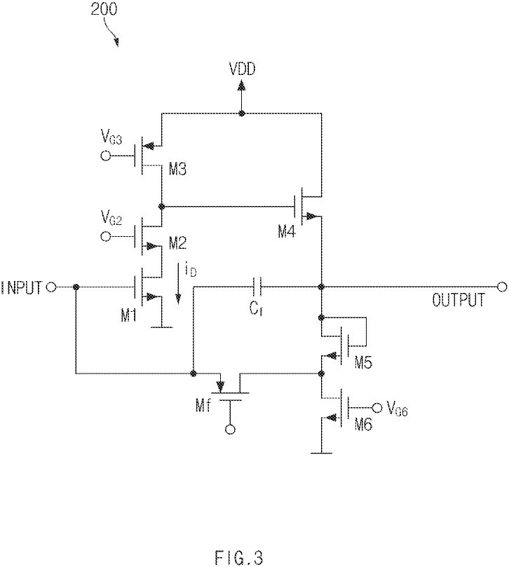

FIG. 3 is a circuit diagram illustrating a structure of a preamplifier, according to an embodiment of the present disclosure.

Referring to FIG. 3, the preamplifier 200 may include a plurality of transistors M1 to M6. Voltages V_{G2}, V_{G3}, and V_{G6} denote gate voltages of the second NMOS transistor M2, the third PMOS transistor M3, and the sixth NMOS transistor M6, respectively.

According to an embodiment, the preamplifier 200 may be a cascode amplifier or a charge sensitive amplifier. The preamplifier 200 may include a feedback resistor and a feedback capacitor. In this case, as the feedback resistance of the preamplifier 200 increases, noise caused by the preamplifier 200 is reduced. Therefore, it is advantageous in terms of noise reduction to set the feedback resistance of the preamplifier 200 high. However, to increase the feedback resistance of the preamplifier 200, the resistance component occupies a lot of space in the integrated circuit, so the degree of integration is lowered, the area of the integrated circuit is increased, and capacitance is generated by the resistance component. Therefore, the preamplifier 200 requires a design that increases the degree of integration and reduces the volume while increasing the feedback resistance.

According to the embodiment, to solve the above issues, the preamplifier 200 may have the feedback resistance increased by using a MOS transistor. For example, the feedback resistance of the preamplifier 200 may have 100 megaohms (MΩ) or more.

According to the embodiment, the preamplifier 200 may include an input terminal and an output terminal, and a source of the first NMOS transistor M1 may be grounded and a gate of the first NMOS transistor M1 may be connected to the input terminal of the preamplifier 200. A source of the second NMOS transistor M2 may be connected to a drain of the first NMOS transistor M1. The third PMOS transistor M3 may have a drain connected to the drain of the second NMOS transistor M2 and a source connected to a supply voltage VDD. The fourth NMOS transistor M4 may have a gate connected to the drain of the second NMOS transistor M2 and the drain of the third PMOS transistor M3, a drain connected to the supply voltage VDD, and a source connected to the output terminal. A gate and a drain of the fifth NMOS transistor M5 may be connected to the output terminal. A source of the sixth NMOS transistor M6 may be grounded, and a drain of the sixth NMOS transistor M6 may be connected to the source of the fifth NMOS transistor M5. A feedback capacitor Cf may be connected in parallel between the input terminal and the output terminal. A feedback MOS transistor Mf may be connected to the input terminal, the source of the fifth NMOS transistor M5, and the drain of the sixth NMOS transistor M6.

According to an embodiment, the first NMOS transistor M1 and the second NMOS transistor M2 may form a cascode structure and function as a cascode amplifier that amplifies and outputs an input voltage.

According to an embodiment, the third PMOS transistor M3 may function as a bias resistor of the cascode amplifier. The voltage V_{G3} represents the gate voltage of the third PMOS transistor M3. According to an embodiment, the gate of the third PMOS transistor M3 is connected to a current mirror to serve as a current source providing a bias current to the cascode amplifier.

According to an embodiment, the fourth NMOS transistor M4 may serve as a source follower. The source follower may act like a buffer that transfers the gate input to the source which is the output terminal. The fourth NMOS transistor M4 may receive the output of the cascode amplifier through its gate and may transfer the received output to the output terminal.

According to the embodiment, the fifth NMOS transistor M5 and the sixth NMOS transistor M6 may allow voltages between the feedback MOS transistors Mf to be the same.

Noise may be reduced by adjusting the channel width and channel length of each transistor constituting the preamplifier 200. According to an embodiment, the ratio of the channel length to width of the first NMOS transistor may be greater than the ratio of the channel length to width of the third PMOS transistor.

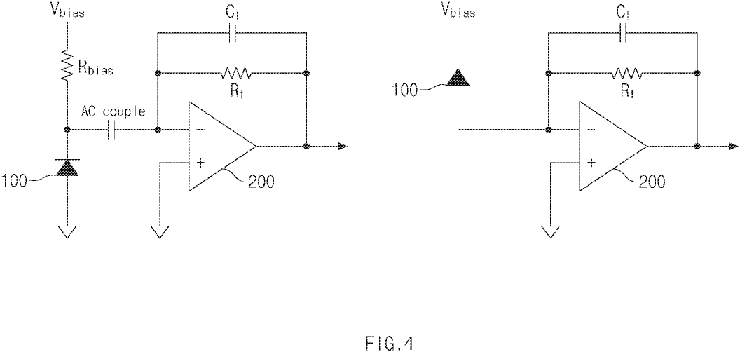

FIG. 4 is a diagram illustrating a DC connection method and an AC connection method of a preamplifier, according to an embodiment of the present disclosure.

Referring to FIG. 4, a DC connection method and an AC connection method may be adjusted using a coupling capacitor. In the case of an AC connection method, a coupling capacitor (AC couple) may be connected between the preamplifier 200 and the detector 100. Vbias and Rbias mean a bias voltage and a bias resistance, respectively.

According to the embodiment, the feedback MOS transistor Mf has a source connected to the input terminal of the preamplifier 200, may include an NMOS transistor when the preamplifier 200 is the AC connection method, and may include a PMOS transistor when the preamplifier 200 is the DC connection method.

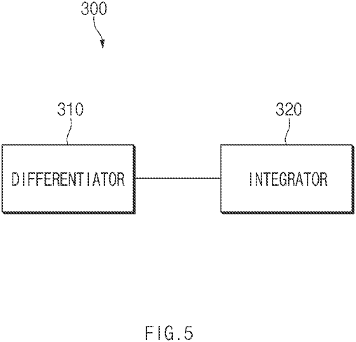

FIG. 5 is a diagram illustrating a configuration of the filter 300, according to an embodiment of the present disclosure.

Referring to FIG. 5, the filter 300 may include a differentiator 310 and an integrator 320.

According to an embodiment, the filter 300 may include a semi-Gaussian filter. The semi-Gaussian filter may reduce noise through a band pass filter function. According to an embodiment, the semi-Gaussian filter may include one CR circuit and at least one RC circuit. Here, the CR circuit may refer to a circuit that outputs a voltage across a resistor when a capacitor and the resistor are connected in series, and the RC circuit may refer to a circuit that outputs a voltage across a capacitor when a resistor and the capacitor are connected in series. Since the CR circuit differentiates and outputs an input, it can serve as a differential circuit, and since the RC circuit integrates and outputs an input, it can serve as an integrating circuit.

According to an embodiment, the differentiator 310 may include one CR circuit, and the integrator 320 may include at least one RC circuit.

According to an embodiment, the differentiator 310 and the integrator 320 may be configured as an active filter to perform amplification and filtering.

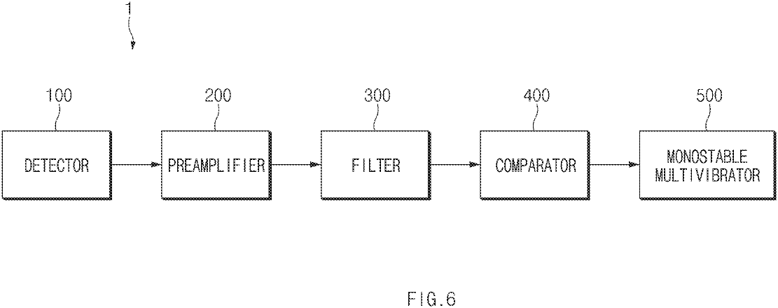

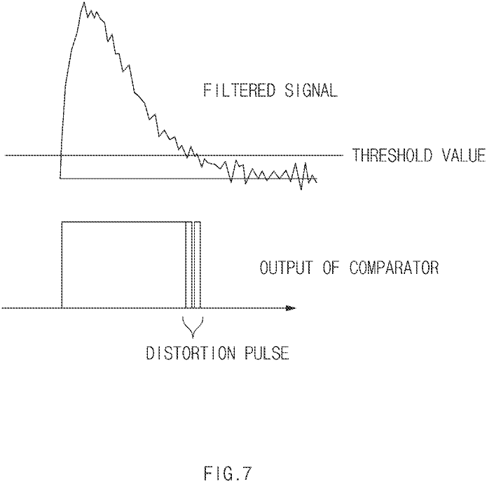

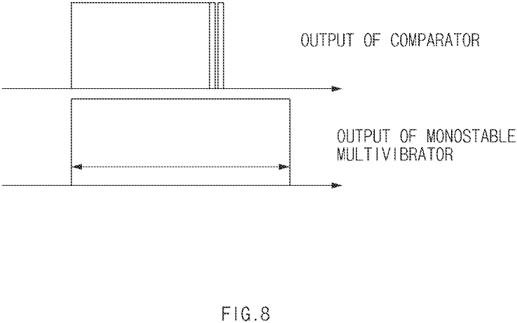

FIG. 6 is a diagram illustrating an entropy generation apparatus further including a monostable multivibrator, according to an embodiment of the present disclosure. FIGS. 7 and 8 are diagrams for describing an operation of a monostable multivibrator of the entropy generation apparatus, according to an embodiment of the present disclosure.

First, referring to FIG. 6, the entropy generation apparatus 1 may include a monostable multivibrator 500. According to the embodiment, the entropy generation apparatus 1 illustrated in FIG. 2 may further include the monostable multivibrator 500 compared to the entropy generation apparatus 1 illustrated in FIG. 1.

According to an embodiment, the entropy generation apparatus 1 may include a monostable multivibrator 500 that generates a stable pulse by removing distortion of the pulse generated by the comparator 400.

Referring to FIG. 7, while the comparator 400 compares the filtered signal with the threshold to generate a pulse, a part of the noise included in the filtered signal exceeds the threshold, and thus a distortion pulse may be generated.

Referring to FIG. 8, the monostable multivibrator 500 may generate a stable pulse from which the distortion pulse is removed from the output of the comparator 400 including the distortion pulse.

The filtered signal generated by the filter 300 may include noise that is not removed, and in this case, a pulse output from the comparator 400 may include a distortion pulse due to the noise that is not removed. According to the embodiment, the monostable multivibrator 500 may remove distortion from the pulse generated by the comparator 400 such that the distortion pulse is not included.

According to the embodiment, the monostable multivibrator 500 may output a stable pulse when the pulse generated by the comparator 400 is input. The monostable multivibrator 500 may output a pulse lasting for a certain period of time when a change from a low value to a high value of the pulse is input. In this case, the monostable multivibrator 500 may maintain the existing output pulse without outputting a pulse even if the pulse is re-input while generating the output pulse.

According to the embodiment, the distortion pulse may be removed by adjusting the pulse duration of the monostable multivibrator 500.

According to the embodiment, the pulse duration of the monostable multivibrator 500 may be set to be longer than the operating time of the comparator 400. The operating time of the comparator 400 may mean a time during which the comparator 400 operates to receive an analog signal and to generate a pulse. Since the distortion pulse generated by the comparator 400 is generally generated at both ends of the output of the comparator 400, by adjusting the pulse duration of the monostable multivibrator 500 longer than the operating time of the comparator 400, the distortion pulses present at both ends of the pulse generated by the comparator 400 may be effectively removed.

According to the embodiment, the pulse duration of the monostable multivibrator 500 may be determined by a time constant. The time constant is a constant representing response characteristics of a circuit or device and may have a different value depending on the circuit or device. According to the embodiment, by adjusting the time constant of the monostable multivibrator 500, the pulse duration of the monostable multivibrator 500 may be set to be longer than the operating time of the comparator 400. For example, the pulse duration of the monostable multivibrator 500 may be set to twice the operating time of the comparator.

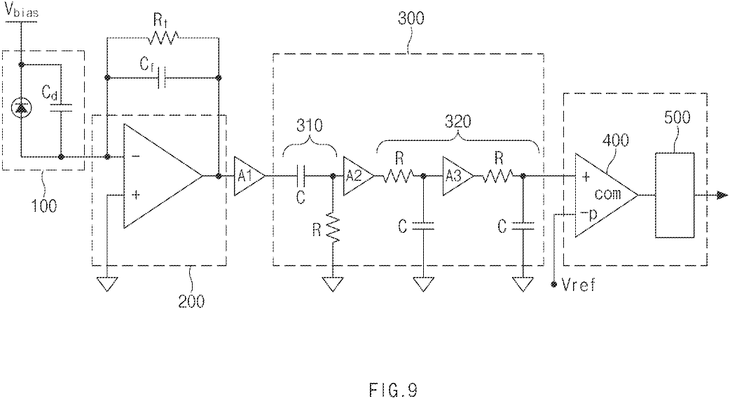

FIG. 9 is a diagram illustrating an entire circuit of an entropy generation apparatus, according to an embodiment of the present disclosure.

Referring to FIG. 9, the entropy generation apparatus 1 may include the detector 100, the preamplifier 200, the filter 300, the comparator 400, and the monostable multivibrator 500, and the filter 300 may include the differentiator 310 and the integrator 320.

In FIG. 9, Cd represents a detection capacitance of the detector 100, Rf and Cf represent a feedback resistance and a feedback capacitance of the preamplifier 200, respectively, Vbias represents a bias voltage, and Vref represents a reference voltage of the comparator 400. R and C may mean resistors and capacitors present in circuits constituting the differentiator 310 and the integrator 320.

According to the embodiment, through the noise reduction design of the detector 100, the preamplifier 200, the filter 300, and the comparator 400, the entropy generation apparatus 1 may use the beta ray source emitting low-energy beta rays as the entropy source.

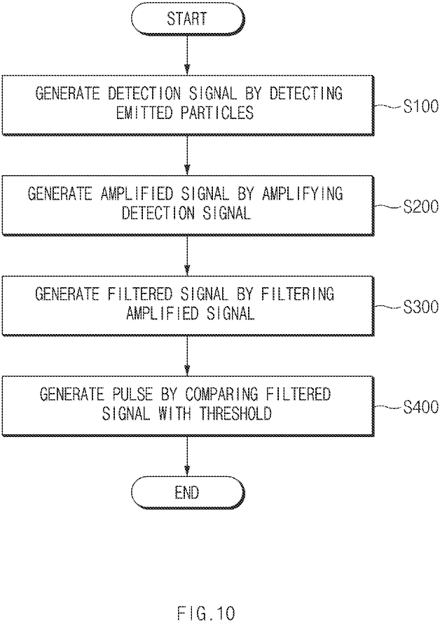

FIG. 10 is a flowchart for describing an entropy generation method, according to an embodiment of the present disclosure.

Referring to FIG. 10, the entropy generation method may include generating a detection signal by detecting emitted particles (S100), generating an amplified signal by amplifying the detection signal (S200), generating a filtered signa by filtering the amplified signal (S300), and generating a pulse by comparing the filtered signal with a threshold (S400).

In step S100, the detector 100 may generate a detection signal by detecting particles emitted from a radiation source. According to an embodiment, the detector 100 may include the PIN diode 110.

In step S200, the preamplifier 200 may generate an amplified signal by amplifying the detection signal. According to an embodiment, the preamplifier 200 may have a single ended structure.

In step S300, the filter 300 may generate a filtered signal by filtering the amplified signal. According to an embodiment, the filter 300 may include a semi-Gaussian filter, and may include the differentiator 310 and the integrator 320.

In step S400, the comparator 400 may generate a pulse based on a result of comparing the filtered signal with a threshold.

In the above, even though all the components constituting the embodiments disclosed in this specification have been described as being combined or operated as one, the embodiments disclosed in this specification are not necessarily limited to these embodiments. That is, within the scope of the objectives of the embodiments disclosed in this specification, all of the components may be selectively combined with one or more to operate.

In addition, since terms such as “include”, “comprise”, or “having” described above mean that the corresponding component may be inherent unless otherwise stated, the terms should be construed as possibly including more other components rather than excluding other components. All terms, including technical or scientific terms, have the same meaning as commonly understood by a person of ordinary skill in the art to which the embodiments disclosed in this specification belong, unless defined otherwise. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

According to the embodiments disclosed in this specification, the entropy generation apparatus may effectively detect low-energy beta rays and use them as an entropy source by reducing inherent noise through circuit design.

In addition, according to the embodiments disclosed in this specification, the entropy generating apparatus may generate high-speed random numbers and increase the efficiency of random number generation by using a plurality of low-energy beta rays having a high number of regulatory exemptions.

In addition, according to the embodiments disclosed in this specification, the entropy generation apparatus may be used for a long period of time by reducing damage to a circuit sensor such as a semiconductor sensor by using low-energy beta rays.

In addition, according to the embodiments disclosed in this specification, the entropy generation apparatus may be miniaturized using low-energy beta rays, and thus its utilization in security fields such as the loT may be increased.

In addition, various effects directly or indirectly identified through the disclosure may be provided.

The above description is merely illustrative of the technical idea of the present disclosure, and those of ordinary skill in the art to which the present disclosure pertains will be able to make various modifications and variations without departing from the essential characteristics of the present disclosure. Therefore, embodiments of the present disclosure are not intended to limit the technical spirit of the present disclosure, but provided only for the illustrative purpose. The scope of protection of the present disclosure should be construed by the attached claims, and all technical sprit within an equivalent scope thereof should be construed as being included within the scope of the present disclosure.

What is claimed is:

1. An entropy generation apparatus comprising:
a detector configured to detect particles emitted from the radiation source to generate a detection signal;
a preamplifier configured to amplify the detection signal to generate an amplified signal;
a filter configured to filter the amplified signal to generate a filtered signal; and
a comparator configured to generate a pulse based on a result of comparing the filtered signal with a threshold.

2. The entropy generation apparatus of claim 1, comprising:
a monostable multivibrator configured to generate a stable pulse by removing distortion of the pulse.

3. The entropy generation apparatus of claim 2, wherein a pulse duration time of the monostable multivibrator is set to more than an operating time of the comparator.

4. The entropy generation apparatus of claim 1, wherein the radiation source comprises a beta ray source.

5. The entropy generation apparatus of claim 1, wherein the detector comprises a PIN diode.

6. The entropy generation apparatus of claim 5, wherein the PIN diode has a detect capacitance of 10 picofarads (pf) or less.

7. The entropy generation apparatus of claim 1, wherein the preamplifier has a single ended structure.

8. The entropy generation apparatus of claim 1, wherein the preamplifier comprises:
an input terminal and an output terminal;
a first NMOS transistor having a gate connected to the input terminal and a source grounded;
a second NMOS transistor having a source connected to a drain of the first NMOS transistor;
a third PMOS transistor having a drain connected to a drain of the second NMOS transistor and a source connected to a supply voltage;
a fourth NMOS transistor having a gate connected to the drain of the second NMOS transistor and the drain of the third PMOS transistor, a drain connected to the supply voltage, and a source connected to the output terminal;
a fifth NMOS transistor having a gate and a drain connected to the output terminal;
a sixth NMOS transistor having a source grounded and a drain connected to a source of the fifth NMOS transistor;
a feedback capacitor connected in parallel between the input terminal and the output terminal; and
a feedback transistor connected to the input terminal and the source of the fifth NMOS transistor and the drain of the sixth NMOS transistor.

9. The entropy generation apparatus of claim 8, wherein the feedback transistor has a source connected to the input terminal,
when the preamplifier is an alternating current (AC) connection type, it includes an NMOS transistor, and
when the preamplifier is a direct current (DC) connection method, it includes a PMOS transistor.

10. The entropy generation apparatus of claim 8, wherein a ratio of a channel length to a width of the first NMOS transistor is greater than that of the third PMOS transistor.

11. The entropy generation apparatus of claim 1, wherein the filter comprises a semi-Gaussian filter.

12. The entropy generation apparatus of claim 1, wherein the filter comprises a differentiator configured to receive the amplified signal and output a differential signal; and
an integrator configured to receive the differential signal and generate the filtered signal.

13. The entropy generation apparatus of claim 1, wherein the comparator compares the filtered signal with a threshold value and generates a pulse when a magnitude of the filtered signal is greater than or equal to that of the threshold value.

14. An entropy generation apparatus comprising:
generating a detection signal by detecting particles emitted from the radiation source;
generating an amplified signal by amplifying the detection signal;
generating a filtered signal by filtering the amplified signal; and
generating a pulse based on a result of comparing the filtered signal with a threshold value.
